(19) United States
(12) Patent Application Publication
(10) Pub. No.: US 2006/0001092 A1
(43) Pub. Date: Jan. 5, 2006

(54) Thin film transistor (TFT) and flat panel display including TFT

(76) Inventor: Tae-Seong Kim, Suwon-si (KR)

Correspondence Address: Robert E. Bushnell, Suite 300, 1522 K Street, N.W., Washington, DC, 20005-1202, US

(21) Appl. No.: 11/169,329

(22) Filed: Jun. 29, 2005

(30) Foreign Application Priority Data
Jun. 30, 2004 (KR) 10-2004-0050422

(51) Int. Cl. H01L 27/01

(52) U.S. Cl. 257/347

(57) ABSTRACT

A Thin Film Transistor (TFT) includes: an active layer including a channel region, a source region, and a drain region; a gate electrode insulated from the active layer and adapted to supply a signal to the channel region; and a source electrode and a drain electrode, insulated from the gate electrode, and adapted to be connected to the source and drain regions, respectively, the source and drain electrodes including a first metal layer pattern and a second metal layer pattern, the first metal layer pattern adapted to be in contact with the source and drain regions of the active layer and containing at least one metal selected from the group consisting of Cr, Cr alloys, Mo, and Mo alloys, and the second metal layer pattern being arranged on the first metal layer pattern and containing at least one metal selected from the group consisting of Ti, Ti alloys, Ta, and Ta alloys; wherein the first metal layer pattern has a thickness of 500 Å or less. The TFT has a low interconnection resistance of source/drain electrodes, prevents contamination from an active layer, has improved contact resistance with a pixel electrode, and facilitates the supply of hydrogen to the active layer to improve mobility, on-current, and threshold current. The thickness of a molybdenum alloy-based layer of source/drain electrodes is controlled to provide better uniformity.

### CROSS-REFERENCE TO RELATED APPLICATIONS

Furthermore, the present application is related to a co-pending U.S. applications, Serial No. (to be determined), entitled THIN FILM TRANSISTOR (TFT) AND FLAT PANEL DISPLAY INCLUDING THE TFT AND THEIR METHODS OF MANUFACTURE, based upon Korean Patent Application Serial No. 10-2004-0050421 filed in the Korean Intellectual Property Office on 30 Jun. 2004, and filed in the U.S. Patent & Trademark Office concurrently with the present application.

### CLAIM OF PRIORITY

This application makes reference to, incorporates the same herein, and claims all benefits accruing under 35 U.S.C. §119 from an application entitled THIN FILM TRANSISTOR AND FLAT PANEL DISPLAY DEVICE COMPRISING THE SAME filed with the Korean Industrial Property Office on Jun. 30, 2004 and there duly assigned Serial No. 10-2004-0050422.

### BACKGROUND OF THE INVENTION

1. Field of the Invention

The present invention relates to a Thin Film Transistor (TFT) and a flat panel display including the TFT. More particularly, the present invention relates to a TFT having an improved structure of an interlayer insulating film and source/drain electrodes and a flat panel display including the TFT.

2. Description of the Related Art

Flat panel displays, such as Liquid Crystal Displays (LCDs) and organic and inorganic ElectroLuminescent (EL) displays, can be either Passive Matrix (PM) displays or Active Matrix (AM) displays, according to their driving mode. In PM flat panel displays, anode electrodes and cathode electrodes are respectively arranged in columns and rows, and scanning signals from a row driving circuit are supplied to the cathodes, with one row being selected. Also, data signals are input to each pixel by a column driving circuit. On the other hand, in AM flat panel displays, signals input to each pixel are controlled using a TFT. AM flat panel displays have a high bandwidth, and thus are widely used as displays for moving pictures.

A TFT in a a flat panel display includes an active layer formed of a semiconductor is located on a substrate. A gate insulating layer is located on the active layer and a gate electrode is located on the gate insulating layer. The gate electrode is covered with an interlayer insulating film. Contact holes are formed through the gate insulating layer and the interlayer insulating film, exposing source/drain regions of the active layer. Source/drain electrodes are located on the interlayer insulating film and contact the source/drain regions of the active layer through the contact holes. The source/drain electrodes can be formed simultaneously with a variety of signal interconnections of the flat panel display.

The source/drain electrodes and the signal interconnections can be formed of molybdenum or its alloys. Molybdenum has a high specific resistance, increasing the interconnection resistance of the source/drain electrodes and the signal interconnections. Thus, signal delay can be induced in the flat panel display, including the TFT, deteriorating the image quality of the flat panel display. To overcome the problem, there has been trials of double-layer structured source/drain electrodes and signal interconnections, comprised of an aluminum layer having a low resistance and a molybdenum layer. However, one of the source/drain electrodes comes in contact with an ITO layer of a pixel electrode. In this case, an oxide layer can form between the aluminum layer and the ITO layer, increasing the contact resistance between the pixel electrode and the source/drain electrodes.

### SUMMARY OF THE INVENTION

A Thin Film Transistor (TFT) of the present invention and a flat panel display including the TFT of the present invention each has a low interconnection resistance of source/drain electrodes, prevents contamination from an active layer, has an improved contact resistance with a pixel electrode, and facilitates the supply of hydrogen to the active layer so that mobility, on-current, and threshold current are excellent.

The present invention also provides a TFT and a flat panel display comprising the TFT in which the thickness of a molybdenum alloy-based layer of source/drain electrodes is controlled to improve the uniformity of the layer.

According to one aspect of the present invention, a Thin Film Transistor (TFT) is provided comprising: an active layer including a channel region, a source region, and a drain region; a gate electrode insulated from the active layer and adapted to supply a signal to the channel region; and a source electrode and a drain electrode, insulated from the gate electrode, and adapted to be connected to the source and drain regions, respectively, the source and drain electrodes including a first metal layer pattern and a second metal layer pattern, the first metal layer pattern adapted to be in contact with the source and drain regions of the active layer and containing at least one metal selected from the group consisting of Cr, Cr alloys, Mo, and Mo alloys, and the second metal layer pattern being arranged on the first metal layer pattern and containing at least one metal selected from the group consisting of Ti, Ti alloys, Ta, and Ta alloys; wherein the first metal layer pattern has a thickness of 500 Å or less.

The second metal layer pattern preferably further contains at least one metal selected from the group consisting of Al, AlSi, AlNd, and AlCu.

The second metal layer pattern and a capping metal layer pattern containing at least one metal selected from the group consisting of Ti, Ti alloys, Ta, and Ta alloys, are preferably layered sequentially from the active layer.

The second metal layer pattern having a protective layer pattern containing at least one metal selected from the group consisting of Ti, Ti alloys, Ta, and Ta alloys, an aluminum-based metal layer pattern containing at least one metal selected from the group consisting of Al, AlSi, AlNd, and AlCu, and a capping metal layer pattern containing at least one metal selected from the group consisting of Ti, Ti alloys, Ta, and Ta alloys, are preferably layered sequentially from the active layer.

The first metal layer pattern preferably has a thickness of 100 to 500 Å.

The active layer preferably comprises polycrystalline silicon.

According to another aspect of the present invention, a flat panel display including at least one TFT is provided, the at least one TFT comprising: an active layer including a channel region, a source region, and a drain region; a gate electrode insulated from the active layer and adapted to supply a signal to the channel region; and a source electrode and a drain electrode, insulated from the gate electrode, and adapted to be connected to the source and drain regions, respectively, the source and drain electrodes including a first metal layer pattern and a second metal layer pattern, the first metal layer pattern adapted to be in contact with the source and drain regions of the active layer and containing at least one metal selected from the group consisting of Cr, Cr alloys, Mo, and Mo alloys, and the second metal layer pattern being arranged on the first metal layer pattern and containing at least one metal selected from the group consisting of Ti, Ti alloys, Ta, and Ta alloys; wherein the first metal layer pattern has a thickness of 500 Å or less.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a cross-sectional view of a Thin Film Transistor (TFT) in a flat panel display;

FIG. 2 is a cross-sectional view of a TFT in a flat panel display according to an embodiment of the present invention;

FIG. 3 is a graph of the relationship between the thickness of a first metal layer pattern and variations in its thickness;

FIGS. 4 through 6 are cross-sectional views of a method of manufacturing the TFT of FIG. 2; and

FIG. 7 is a cross-sectional view of a flat panel display including the TFT of FIG. 2.

### DETAILED DESCRIPTION OF THE INVENTION

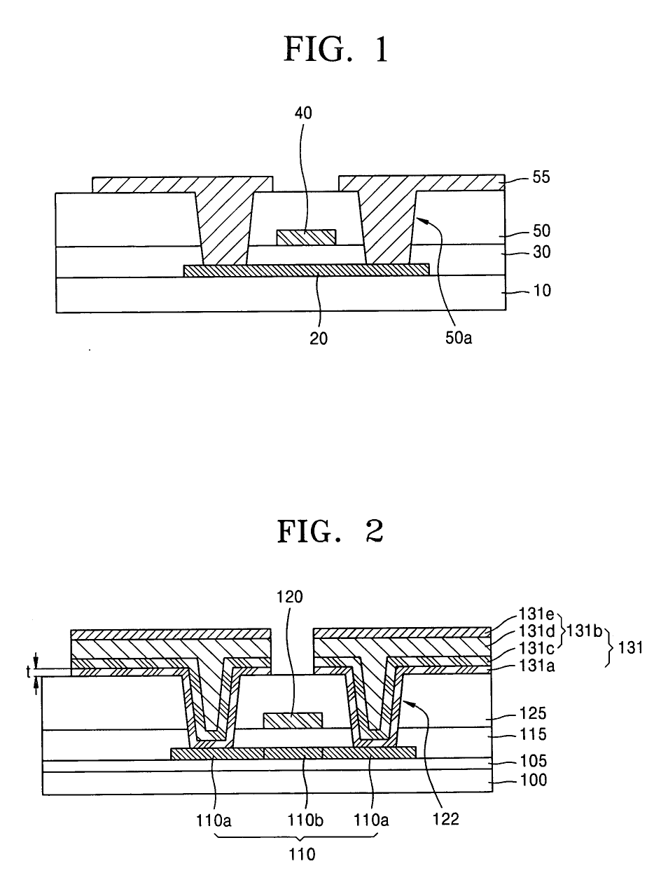

FIG. 1 is a cross-sectional view of a TFT in a flat panel display.

Referring to FIG. 1, an active layer 20 formed of a semiconductor is located on a substrate 10. A gate insulating layer 30 is located on the active layer 20 and a gate electrode 40 is located on the gate insulating layer 30. The gate electrode 40 is covered with an interlayer insulating film 50. Contact holes 50a are formed through the gate insulating layer 30 and the interlayer insulating film 50, exposing source/drain regions of the active layer 20. Source/drain electrodes 55 are located on the interlayer insulating film 50 and contact the source/drain regions of the active layer 20 through the contact holes 50a. The source/drain electrodes 55 can be formed simultaneously with a variety of signal interconnections (not shown) of the flat panel display.

The source/drain electrodes 55 and the signal interconnections can be formed of molybdenum or its alloys. Molybdenum has a high specific resistance, increasing the interconnection resistance of the source/drain electrodes 55 and the signal interconnections. Thus, signal delay can be induced in the flat panel display, including the TFT, deteriorating the image quality of the flat panel display. To overcome the problem, there has been trials of double-layer structured source/drain electrodes 55 and signal interconnections, comprising an aluminum layer having a low resistance and a molybdenum layer. However, one of the source/drain electrodes 55 comes in contact with an ITO layer of a pixel electrode (not shown), and an oxide layer can form between the aluminum layer and the ITO layer, increasing the contact resistance between the pixel electrode and the source/drain electrodes 55.

Hereinafter, the present invention will be described in more detail with reference to the accompanying drawings, in which exemplary embodiments of the present invention are shown. The present invention can, however, be embodied in many different forms and should not be construed as being limited to the embodiments set forth herein. The embodiments set forth herein are provided so that the descriptions in the specification can be clear and complete and those of ordinary skill in the art can fully understand the concepts of the present invention. In the drawings, it will be understood that when a layer is referred to as being “on” another layer or substrate, it can be directly on the other layer or substrate or intervening layers can also be present therebetween. Like reference numerals denote like elements throughout the specification.

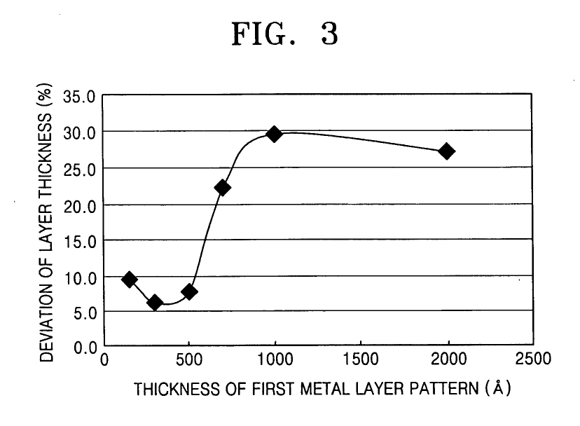

FIG. 2 is a cross-sectional view of a TFT in a flat panel display according to an embodiment of the present invention. Referring to FIG. 2, the TFT is located on a substrate 100. The substrate 100 can be formed of glass, plastic, or metal. A buffer layer 105 is located on the substrate 100. The buffer layer 105 protects the TFT, manufactured in a subsequent process, from impurities, such as alkali ions, which flow out of the substrate 100. The buffer layer 105 can be formed of silicon oxide or silicon nitride.

An amorphous silicon layer can be layered on the buffer layer 105 and crystallized to form a polycrystalline silicon layer. Crystallization of the amorphous silicon layer can be performed using Excimer Laser Annealing (ELA), Sequential Lateral Solidification (SLS), Metal Induced Crystallization (MIC), or Metal Induced Lateral Crystallization (MILC). The polycrystalline silicon layer is patterned to form an active layer 110 on the substrate 100. The active layer 110 has source/drain regions 110a doped with n-type or p-type impurities and a channel region 110b which connects the source/drain regions 110a to each other.

A Low Doping Density (LDD) region is arranged between the channel region 110b and the source/drain regions 110a. The LDD region reduces a local electric field increase in the channel region 110b to reduce the on-current or current mobility of the channel region 110b. The LDD region is doped with the same type of impurities as the source/drain regions 110a, but has a lower density of the doping impurities than the source/drain regions 110a. A gate insulating layer 115 covers the active layer 110, and a gate electrode 120 is located on the gate insulating layer 115. A variety of conductive metal materials, for example, MoW, Al, Cr, or Al/Cu, etc, can be used for the gate electrode 120.

The gate insulating layer 115 can be formed of silicon nitride and/or silicon oxynitride, or other suitable materials.

The gate electrode 120 is covered with an interlayer insulating film 125 formed of silicon nitride and/or silicon oxynitride etc. Source/drain electrodes 131 are located on the interlayer insulating film 125 and through via holes 122 formed in the interlayer insulating film 125 and the gate insulating layer 115 so that the source/drain electrodes 131 respectively contact the source/drain regions 110a of the active layer 110. The source/drain electrodes 131 can comprise a first metal layer pattern 131a and a second metal layer pattern 131b, layered sequentially from the active layer 110. The first metal layer pattern 131a can contain chromium (Cr), Cr alloys, molybdenum (Mo), and/or Mo alloys, etc., which are heat-resistant metals. The second metal layer pattern 131b can contain titanium (Ti), tantalum (Ta) or other materials.

Due to its constituent materials, the first metal layer pattern 131a can exhibit excellent heat stability during a subsequent heat-treatment process, and have excellent anti-corrosive properties, as well as enhancing attachment between the source/drain electrodes 131 and the active layer 110 and insulating layers 115 and 125.

According to an embodiment of the present invention, the second metal layer pattern 131b can contain aluminum (Al), aluminum-silicon (AlSi), aluminum-neodymium (AlNd) and/or aluminum-copper (AlCu) etc.

The second metal layer pattern 131b can have a structure in which a protective layer pattern 131c, an aluminum-based metal layer pattern 131d, and a capping metal layer pattern 131e are layered sequentially from the active layer 110.

The aluminum-based metal layer pattern 131d can be formed of a metal containing Al. Examples of the aluminum-based metal can include aluminum (Al), aluminum-silicon (AlSi), aluminum-neodymium (AlNd), and aluminum-copper (AlCu), as well as others, and preferably, the aluminum-based metal is AlSi. The use of the aluminum-based metal can increase electrical conductivity of the source/drain electrodes 131, thus reducing interconnection resistance of the source/drain electrodes 131.

The capping metal layer pattern 131e can be formed of Ti or Ta. The capping metal layer pattern 131e prevents the formation of an oxide layer, when the aluminum-based metal layer pattern 131d comes in contact with a pixel electrode of the flat panel display, as described above. Thus, to prevent deterioration, such as hillock formation, of the aluminum-based metal, the capping metal layer pattern 131e is formed of Ti or Ta, etc.

The protective layer pattern 131c can be located between the first metal layer pattern 131a and the aluminum-based metal layer pattern 131d of the second metal layer pattern 131b. The protective layer pattern 131c can contain Ti or Ta, etc. The protective layer pattern 131c prevents the active layer 110 from contacting the aluminum-based metal layer pattern 131d due to surface roughness of the active layer 110. When the active layer 110 is crystallized using a laser, i.e., ELA or SLS, to form a polycrystalline silicon layer, the polycrystalline silicon layer can have a rough surface due to the formation of surface projections. Without the protective layer pattern 131c, the rough surface can penetrate the first metal layer pattern 131a to contact and damage the aluminum-based metal layer pattern 131d of the second metal layer pattern 131b.

The first metal layer pattern 131a and the second metal layer pattern 131b can be formed by sequentially layering the metals which can form the first metal layer pattern 131a and the second metal layer pattern 131b on the interlayer insulating film 125 in which source/drain contact holes 122 have been formed, and then patterning the layered metals simultaneously.

The first metal layer pattern 131a can have a thickness (t) of 500 Å or less.

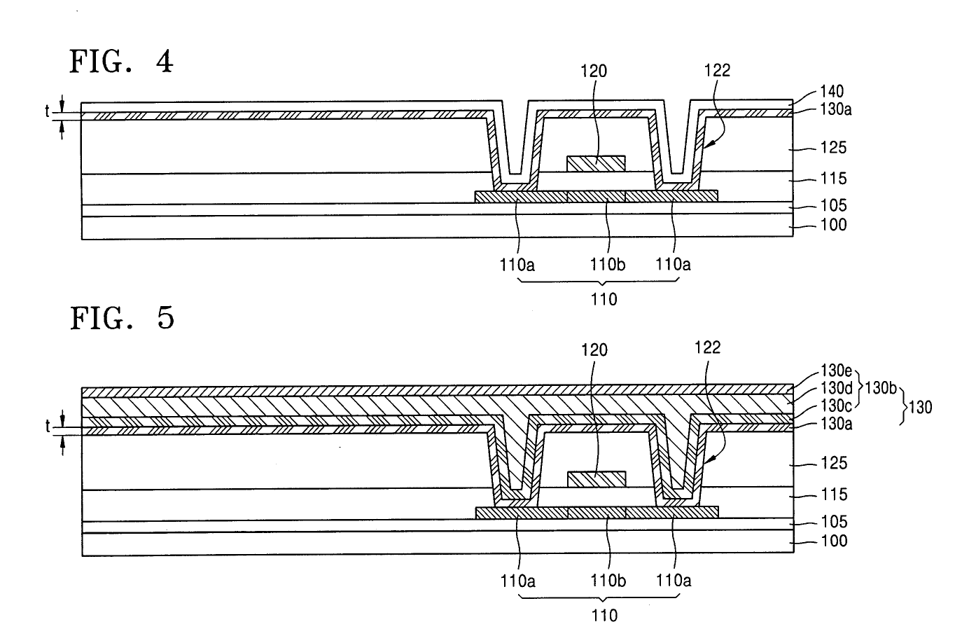

The simultaneous patterning of the layered metals is usually performed by dry etching. As seen from FIG. 3, if the thickness (t) of the first metal layer pattern 131a is 500 Å or less, the deviation in thickness (t) is 10% or less.

Furthermore, the thickness of the first metal layer pattern 131a can be 100 Å or more considering the lower limit of thickness which can be formed by deposition.

A method of manufacturing the TFT according to an exemplary embodiment of the present invention is explained below.

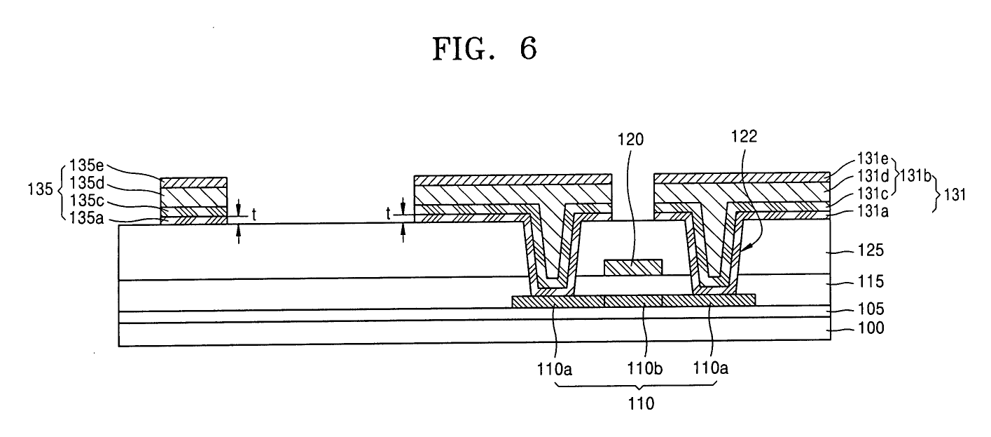

First, as illustrated in FIG. 4, an amorphous silicon layer is layered on the substrate 100 on which the buffer layer 105 has been formed, and is crystallized to form a polycrystalline silicon layer. The polycrystalline silicon layer is patterned to form the active layer 110. Crystallization of the amorphous silicon layer can be performed using ELA, SLS, MIC, or MILC.

Then, the gate insulating layer 115 is formed over all of the substrate 100 including the active layer 110. A gate electrode material is layered on the gate insulating layer 115 and patterned so that the gate electrode 120 can be formed corresponding to a predetermined portion of the active layer 110.

Then, the active layer 110 is doped with ions using the gate electrode 120 as a mask, to form the source/drain regions 110a in the active layer 110. Simultaneously, the channel region 110b is defined between the source/drain regions 110a.

Next, the interlayer insulating film 125 is formed to cover the gate electrode 120, and then the source/drain contact holes 122 are formed through the interlayer insulating film 125 and the gate insulating layer 115, exposing the source/drain regions 110a of the active layer 20.

Then, the first metal layer 130a is layered on the interlayer insulating film 125, the gate insulating layer 115, and the source/drain regions 110a. The first metal layer 130a has a high melting point and excellent heat stability. The first metal layer 130a can contain Cr, Cr alloys, Mo, and/or Mo alloys. As described above, the first metal layer 130a can have a thickness of 500 Å or less. Furthermore, the first metal layer 130a can have a thickness of 100 Å or more.

Next, a silicon nitride layer 140 is formed on the first metal layer 130a. Then, the substrate 100 is heat-treated at a temperature of about 380 degrees C. The heat-treatment activates the ions doped on the source/drain regions 110a. The heat-treatment also diffuses a large amount of hydrogen from the silicon nitride layer 140 into the active layer 110. The hydrogen diffused into the active layer 110 prevents dangling bonds in the active layer 110. The first metal layer 130a is stable at the temperature described above.

When the hydrogenation of the active layer 110 is performed by heat-treatment after the formation of the first metal layer 130a and then the silicon nitride layer 140 as described above, the effect of the hydrogenation is not reduced by half even though the interlayer insulating film 125 is formed of silicon oxide, which is advantageous. Next, etching is performed over the entire silicon nitride layer 140 to expose the first metal layer 130a. The etching of the silicon nitride layer 140 can be performed by dry etching.

Next, as illustrated in FIG. 5, the aluminum-based metal layer 130d and the capping metal layer 130e are sequentially layered on the exposed first metal layer 130a which is heat-resistant.

The aluminum-based metal layer 130d can be formed of a metal containing Al and exhibiting a low specific resistance. The aluminum-based metal layer 130d can contain aluminum (Al), aluminum-silicon (Al Si), aluminum-neodymium (AlNd), and aluminum-copper (AlCu), and is preferably AlSi containing a predetermined ratio of Si. The aluminum-based metal layer 130d has the advantage of a lower specific resistance than the first metal layer 130a . However, the aluminum-based metal layer 130d has a lower melting point and is less thermally stable than the first metal layer 130a. Thus, after the above heat-treatment, the aluminum-based metal layer 130d is layered on the first metal layer 130a.

The aluminum-based metal layer 130d is prevented from contacting the active layer 110 by the first metal layer 130a. If the aluminum-based metal layer 130d contacts the active layer 110, a silicon component of the active layer 110 can diffuse into the aluminum-based metal layer 130d, deteriorating the aluminum-based metal layer 130d. On the other hand, when the active layer 110 is crystallized using a laser, i.e., ELA or SLS, to form a polycrystalline silicon layer, the polycrystalline silicon layer can have a rough surface due to the formation of surface projections. The first metal layer 130a having a thickness of 500 Å or less cannot fully prevent the surface projections of the polycrystalline silicon layer from contacting the aluminum-based metal layer 130d. Thus, to prevent such contact, the protective layer 130c can be formed on the first metal layer 130a before forming the aluminum-based metal layer 130d.

The protective layer 130c can be formed of Ti or Ta. The protective layer 130c can have a thickness of 500 to 1500 Å. When the active layer 110 is an amorphous silicon layer or a polycrystalline silicon layer crystallized using MIC or MILC, i.e, having good surface properties without the surface projections etc., the protective layer 130c need not be formed.

The capping metal layer 130e can be formed of Ti or Ta. The capping metal layer 130e prevents deterioration, such as hillock formation, of the aluminum-based metal layer 130d.

Next, as illustrated in FIG. 6, a photoresist pattern (not shown) is formed on the capping metal layer 130e, and then the capping metal layer 130e, the aluminum-based metal layer 130d, the protective layer 130c, and the first metal layer 130a are sequentially etched using the photoresist pattern as a mask, to produce the source/drain electrodes 131 in which the first metal layer pattern 131a, the protective layer pattern 131c, the aluminum-based metal layer pattern 131d, and the capping metal layer pattern 131e are sequentially layered. The above etching can be performed by dry etching. By giving the first metal layer 130a a thickness of 500 Å or less, uniformity can be increased when simultaneously etching the capping metal layer 130e, the aluminum-based metal layer 130d, the protective layer 130c, and the first metal layer 130a.

On the other hand, other signal interconnection 135 can be formed on the interlayer insulating film 125 at the same time as the source/drain electrodes 131. The signal interconnection 135 has a structure in which the first metal layer pattern 135a, the protective layer pattern 135c, the aluminum-based metal layer pattern 135d, and the capping metal layer pattern 135e are sequentially layered. The interconnection resistance of the signal interconnection 135 can be reduced remarkably by using the aluminum-based metal layer pattern 135d formed of the material having low specific resistance.

The TFT formed in this way can be used in AM organic EL displays or LCDs.

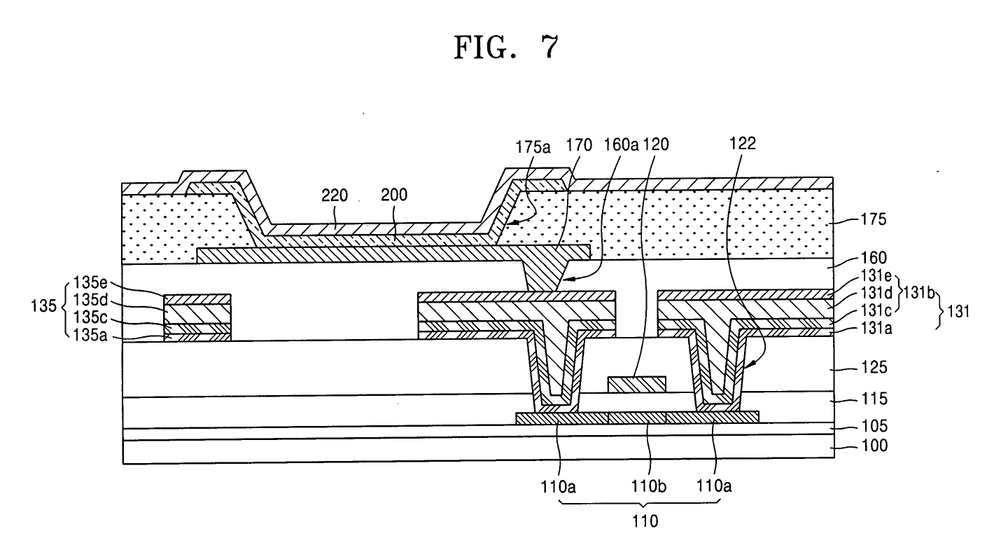

FIG. 7 is a cross-sectional view of a flat panel display comprising the TFT according an embodiment of the present invention, showing sub-pixels of a luminescent region for displaying images.

According to an exemplary embodiment of the present invention, the luminescent region has a plurality of the sub-pixels, and in full-color organic EL displays, the sub-pixels of Red (R), Green (G), and Blue (B) are arranged in various patterns, such as lines, a mosaic or a lattice, to form a pixel. The TFT according to an embodiment of the present invention can also be used in monochrome flat panel displays.

The number and arrangement of TFTs in the organic EL display according to an embodiment of the present invention are not limited to those illustrated in FIG. 7, and can be varied according to the characteristics and driving method of the display.

After the formation of the signal interconnection 135 and the source/drain electrodes 131 as illustrated in FIG. 6, a passivation layer 160 is formed to cover the signal interconnection 135 and the source/drain electrodes 131. The passivation layer 160 can be formed of inorganic materials, such as, silicon oxide, silicon nitride, etc., organic materials, such as acryl, polyimide, BCB, etc., or their combined structure.

A via hole 160a is formed in the passivation layer 160, and then, a pixel electrode 170 is formed on the passivation layer 160 to contact one of the source/drain electrodes 131. A pixel definition layer 175 is then formed to cover the pixel electrode 170 and the passivation layer 160. An opening 175a is formed in the pixel definition layer 175, and then an organic layer 200 is formed on at least the region defined by the opening 175a. The organic layer 200 contains a luminescent material. Next, the opposite electrode 220 is formed on the organic layer 200 to cover all the pixels. The structure of the organic EL display according to an embodiment of the present invention is not limited to the above structure and can include various structures of organic EL displays.

The above organic EL display emits red, green, or blue light according to current flow to display images. The above-noted organic EL display comprises the pixel electrode 170 connected to one of the source/drain electrodes 131 of the TFT, the opposite electrode 220 covering all of the pixels, and the organic layer 200 interposed between the pixel electrode 170 and the opposite electrode 220 and emitting light. The pixel electrode 170 and the opposite electrode 220 are insulated from each other by the organic layer 200 and supply voltages of opposite polarity to the organic layer 200, causing the organic layer 200 emit light.

A low or high molecular weight organic layer can be used as the organic layer 200. The low molecular weight organic layer can have the structure of a Hole Injection Layer (HIL), a Hole Transport Layer (HTL), an EMission Layer (EML), an Electron Transport Layer (ETL), or an Electron Injection Layer (EIL), etc. either alone or in combination. Examples of an organic material that can be used include various organic materials, such as copper phthalocyanine (CuPc), N,N′-di(naphthalene-1-yl)-N,N′-diphenyl-benzidine (NPB), and tris-8-hydroxyquinoline aluminum (Alq3), etc. The low molecular weight organic layer can be formed using vacuum deposition.

The high molecular weight organic layer can have a structure comprised of an HTL and an EML. PEDOT can be used as the material of the HTL, and polyphenylenevinylene (PPV)-based and polyfluorene-based organic material etc. can be used as a material of the EML. The high molecular weight organic layer can be formed using screen printing or inkjet printing.

The organic layer used according to an embodiment of the present invention is not limited the above-noted layers and can include various other layers.

The pixel electrode 170 functions as an anode electrode and the opposite electrode 220 functions as a cathode electrode, or vice versa.

The pixel electrode 170 can be a transparent electrode or a reflection-type electrode. The transparent electrode can comprise ITO, IZO, ZnO, or In₂O₃. The reflection-type electrode can be produced by forming a reflective layer using Ag, Mg, Al, Pt, Pd, Au, Ni, Nd, Ir, Cr, or mixtures thereof, and then forming a layer of ITO, IZO, ZnO, or In₂O₃. The opposite electrode 220 can be a transparent electrode or a reflection-type electrode. When using the transparent electrode, the opposite electrode 220 functions as a cathode electrode. Thus, metals having a low work function, i.e., Li, Ca, LiF/Ca, LiF/Al, Al, Ag, Mg, or their compounds are deposited to face the organic layer 200, and then, a supplementary electrode layer or a bus electrode line can be produced using a material for a transparent electrode, such as ITO, IZO, ZnO, or In₂O₃ on the above deposited metals. The reflection-type electrode can produced by depositing Li, Ca, LiF/Ca, LiF/Al, Al, Ag, Mg, or their compounds as described above over the entire organic layer 200.

On the other hand, in the case of LCDs, a bottom substrate is manufactured by forming a bottom orientation layer (not shown) covering the pixel electrode 170.

In an embodiment of the present invention, the pixel electrode 170 contacts the capping metal layer pattern 131e formed of Ti or Ta, etc. of one of the source/drain electrodes 131 through the via hole 160a. Thus, direct contact of the pixel electrode 170 with the aluminum-based metal layer pattern 131d can be prevented.

The TFT according to an embodiment of the present invention can be used as a switching TFT, a TFT for a compensation circuit, and a TFT for a driver circuit outside a luminescent region, in addition to a TFT which contacts the pixel electrode in the pixel as described above.

According to the present invention as specified above, the following effects can be accomplished.

First, the TFT and the flat panel display which uses it have a low interconnection resistance of source/drain electrodes, preventing contamination from an active layer, and an improved contact resistance with a pixel electrode.

Second, the TFT and the flat panel display which uses it facilitate the supply of hydrogen to an active layer so that mobility, on-current, and threshold current, etc. are excellent

Third, the TFT and the flat panel display which uses it have a molybdenum alloy-based layer of source/drain electrodes of a controlled thickness so that the uniformity of the layer can be increased.

While the present invention has been particularly shown and described with reference to exemplary embodiments thereof, it will be understood by those of ordinary skill in the art that various modifications in form and detail can be made therein without departing from the spirit and scope of the present invention as defined by the following claims.

What is claimed is:

1. A Thin Film Transistor (TFT), comprising:
an active layer including a channel region, a source region, and a drain region;
a gate electrode insulated from the active layer and adapted to supply a signal to the channel region; and
a source electrode and a drain electrode, insulated from the gate electrode, and adapted to be connected to the source and drain regions, respectively, the source and drain electrodes including a first metal layer pattern and a second metal layer pattern, the first metal layer pattern adapted to be in contact with the source and drain regions of the active layer and containing at least one metal selected from the group consisting of Cr, Cr alloys, Mo, and Mo alloys, and the second metal layer pattern being arranged on the first metal layer pattern and containing at least one metal selected from the group consisting of Ti, Ti alloys, Ta, and Ta alloys;
wherein the first metal layer pattern has a thickness of 500 Å or less.

2. The TFT of claim 1, wherein the second metal layer pattern further contains at least one metal selected from the group consisting of Al, AlSi, AlNd, and AlCu.

3. The TFT of claim 2, wherein the second metal layer pattern having an aluminum based metal layer pattern containing at least one metal selected from group consisting of Al, AlSi, AlNd, and AlCu, and a capping metal layer pattern containing at least one metal selected from the group consisting of Ti, Ti alloys, Ta, and Ta alloys, are layered sequentially from the active layer.

4. The TFT of claim 2, wherein the second metal layer pattern having a protective layer pattern containing at least one metal selected from the group consisting of Ti, Ti alloys, Ta, and Ta alloys, an aluminum-based metal layer pattern containing at least one metal selected from the group consisting of Al, AlSi, AlNd, and AlCu, and a capping metal layer pattern containing at least one metal selected from the group consisting of Ti, Ti alloys, Ta, and Ta alloys, are layered sequentially from the active layer.

5. The TFT of claim 1, wherein the first metal layer pattern has a thickness of 100 to 500 Å.

6. The TFT of claim 1, wherein the active layer comprises polycrystalline silicon.

7. A flat panel display including at least one TFT, the at least one TFT comprising:
an active layer including a channel region, a source region, and a drain region;
a gate electrode insulated from the active layer and adapted to supply a signal to the channel region; and
a source electrode and a drain electrode, insulated from the gate electrode, and adapted to be connected to the source and drain regions, respectively, the source and drain electrodes including a first metal layer pattern and a second metal layer pattern, the first metal layer pattern adapted to be in contact with the source and drain regions of the active layer and containing at least one metal selected from the group consisting of Cr, Cr alloys, Mo, and Mo alloys, and the second metal layer pattern being arranged on the first metal layer pattern and containing at least one metal selected from the group consisting of Ti, Ti alloys, Ta, and Ta alloys;
wherein the first metal layer pattern has a thickness of 500 Å or less.

8. The display of claim 7, wherein the second metal layer pattern further contains at least one metal selected from the group consisting of Al, AlSi, AlNd, and AlCu.

9. The display of claim 8, wherein the second metal layer pattern having an aluminum based metal layer pattern containing at least one metal selected from group consisting of Al, AlSi, AINd, and AlCu, and a capping metal layer pattern containing at least one metal selected from the group consisting of Ti, Ti alloys, Ta, and Ta alloys, are layered sequentially from the active layer.

10. The display of claim 8, wherein the second metal layer pattern having a protective layer pattern containing at least one metal selected from the group consisting of Ti, Ti alloys, Ta, and Ta alloys, an aluminum-based metal layer pattern containing at least one metal selected from the group consisting of Al, AlSi, AlNd, and AlCu, and a capping metal layer pattern containing at least one metal selected from the group consisting of Ti, Ti alloys, Ta, and Ta alloys, are layered sequentially from the active layer.

11. The display of claim 7, wherein the first metal layer pattern has a thickness of 100 to 500 Å.

12. The display of claim 7, wherein the active layer comprises polycrystalline silicon.
